(19) United States
(12) Patent Application Publication
(10) Pub. No.: US 2011/0164381 A1
(43) Pub. Date: Jul. 7, 2011

(54) Assembly-supporting Spring Between Rigid Connectors

(76) Inventors: Jeffrey A Lev, Houston, TX (US); Steven S. Homer, Houston, TX (US); Mark S. Tracy, Houston, TX (US)

(21) Appl. No.: 13/062,987

(22) PCT Filed: Oct. 31, 2008
(86) PCT No.: PCT/US2008/082028

§ 371 Date: Mar. 9, 2011

(51) Int. Cl. H05K 7/20; H05K 7/12

(52) U.S. Cl. 361/688; 361/769

(57) ABSTRACT

An assembly comprises a sub-assembly including a semiconductor package coupled to a printed circuit board (PCB). The assembly also comprises multiple rigid connectors that couple the sub-assembly to a support structure. The assembly further comprises a spring, coupled to the support structure and positioned between the multiple rigid connectors, that supports at least some of the sub-assembly.

### BACKGROUND

Integrated circuit packages (e.g., flip-chip packages) generate heat. Heat dissipators coupled to the packages help dissipate heat. Heat dissipators generally couple to such packages using multiple, spring-mounted screws. Over time, the tensions on the springs coupling a heat dissipator to a package can change, causing the heat dissipator to become unevenly coupled to the package. This uneven coupling negatively impacts thermal dissipation from the package.

### BRIEF DESCRIPTION OF THE DRAWINGS

For a detailed description of exemplary embodiments of the invention, reference will now be made to the accompanying drawings in which:

FIG. 1 shows a side-profile view of a chip assembly, in accordance with embodiments;

FIGS. 2a-c show multiple types of wave springs that may be incorporated into the chip assembly shown in FIG. 1, in accordance with embodiments; and

FIG. 3 shows a top-down view of the chip assembly of FIG. 1, in accordance with embodiments.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect, direct, optical or wireless electrical connection. Thus, if a first device couples to a second device, that connection may be through a direct electrical connection, through an indirect electrical connection via other devices and connections, through an optical electrical connection, or through a wireless electrical connection.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Disclosed herein is a system that mitigates the aforementioned problems by using a free-standing spring and multiple, non-spring-mounted screws in lieu of the multiple, spring-mounted screws described above. This system maintains even coupling and constant pressure between the heat dissipator and the package which, in turn, maintain an efficient level of heat dissipation from the package.

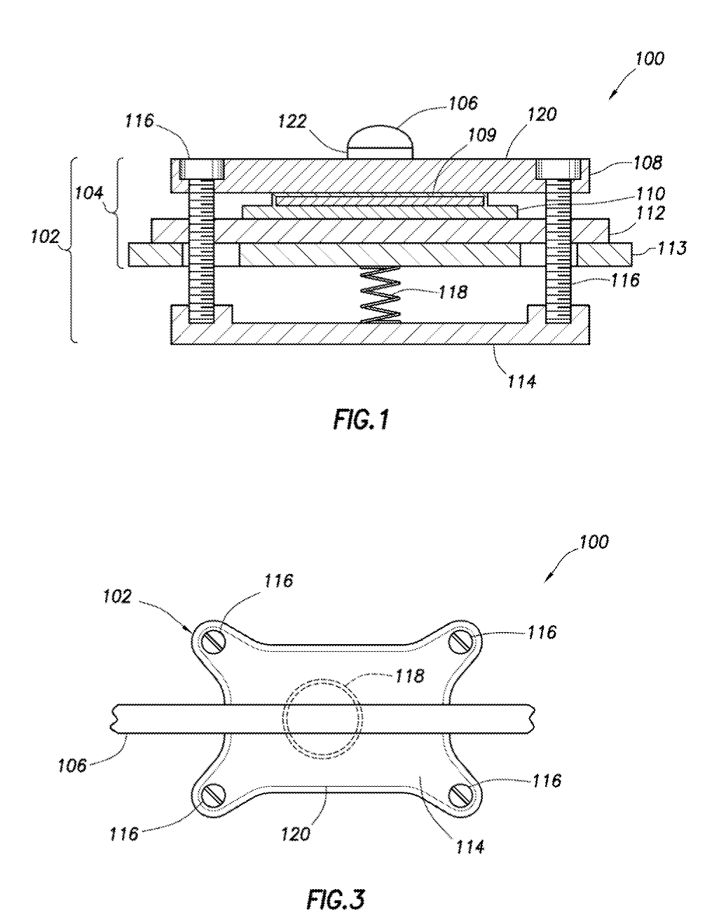

FIG. 1 shows a side-profile view of a system 100 in accordance with various embodiments. The system 100 may be housed within any suitable, electronic device, such as a mobile communication device, a desktop computer, a notebook computer, a television, audio-based or video-based equipment, etc. The system 100 comprises an assembly 102 coupled to a heat dissipator 106. The assembly 102 comprises a sub-assembly 104 that couples to a rigid support plate (RSP) 114 via a spring 118. The sub-assembly 104 includes a top plate 108, a ball grid array (BGA) 110 and a printed circuit board (PCB) 112. The BGA 110 comprises a semiconductor package (e.g., a flip-chip package) that contains a semiconductor die 109 that electrically communicates with the PCB 112. Other structural arrangements besides that shown in FIG. 1 also may be used. The sub-assembly 104 also includes a back plate 113 to which the PCB 112 couples. The heat dissipator 106 couples to a silicon surface 120 of the top plate 108 using any suitable thermal interface material (TIM) 122 (e.g., phase change materials, thermal greases and elastomeric pads).

The top plate 108 receives heat generated by the BGA 110. In turn, the TIM 122 facilitates heat transfer from the top plate 108 to the heat dissipator 106. In at least some embodiments, the efficiency with which the TIM 122 transfers heat depends at least to some degree on the pressure applied to it by compression of the top plate 108 and/or the heat, dissipator 106. Therefore, the pressure applied to the TIM 122 should be and preferably is within a desired, predetermined range to maintain efficient heat dissipation. For similar reasons, the pressure is preferably applied evenly across the TIM 122. As is now described, the system 100 is able to apply pressure evenly across TIM 122 and the applied pressure experiences minimal, if any, drift over time.

The sub-assembly 104 couples to the RSP 114 using the spring 118. The spring 118 supports some or all of the weight of the sub-assembly 104 and/or the heat dissipator 104. Because these components are supported by a spring, they require at least some degree of stability to remain upright. Rigid connectors such as screws 116, which are not spring-mounted, provide this stability to the system 100 by coupling the top plate 108 and the PCB 112 to the RSP 114. Rigid connectors besides screws also may be used. In at least some embodiments, the spring 118 is the only spring in the assembly 102.

A free-standing spring 118 (i.e., a spring that does not have a screw or other rigid connector passing therethrough), positioned as shown in FIG. 1 (e.g., approximately equidistant from the screws 116 (in some embodiments, with a variance less than 3 cm)), is superior over spring-mounted screws at least because it only has a single tension with which it is associated, instead of multiple, different tensions associated with multiple screws. A lack of differing tensions promotes even coupling and satisfactorily constant pressure between the heat dissipator 106 and the top plate 108.

The spring 118 is also preferred at least because it provides a uniform force distribution over all screws, instead of having disparate forces acting on different screws. Having uneven forces on the BGA 110 causes the BGA 110 to tilt and have uneven, inefficient coupling with the heat dissipator. However, with a single, free-standing spring 118, the screws' forces on the top plate 108 remains substantially similar or equal, thereby maintaining an even, efficient coupling with the heat dissipator 106. This even coupling enhances thermal dissipation via the heat dissipator 106.

In at least some embodiments, the spring 118 comprises a crest-to-crest wave spring, but other types of springs (e.g., general coil springs) also may be used. Such wave springs not only occupy less space in comparison to coil springs, but also maintain pressure/tension better than do coil springs. Thus, a manufacturer who adjusts the spring 118 to have a specific pressure will likely be able to maintain that pressure. When the heat dissipator 106 and the top plate 108 are substantially co-planar and have a stable, desired pressure therebetween, thermal dissipation efficiency is enhanced.

In summary, because the screws 116 are not spring-mounted, the screws 116 are not subject to differing tensions, and so the heat dissipator 106 remains evenly coupled to the top plate 108. Specifically, the force between the silicon surface 120 and the heat dissipator 106 (i.e., the force exerted on the TIM 122) is maintained at a desirable level due to a lack of drift in spring tension. Further, the spring 118 maintains co-planarity between the heat dissipator 106 and the silicon surface 122.

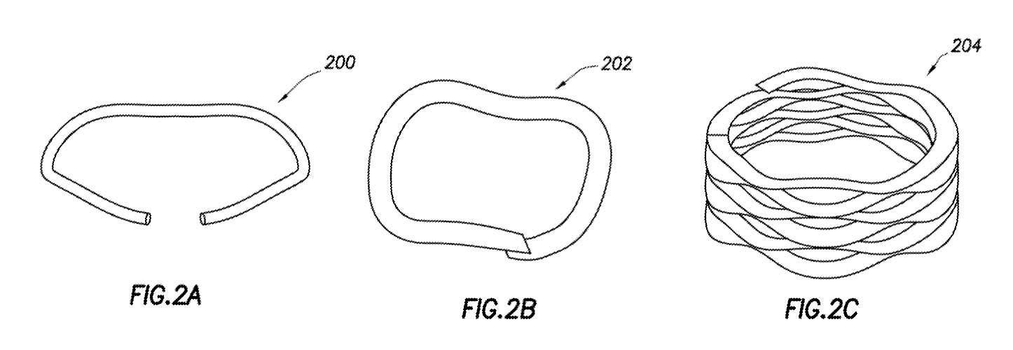

FIGS. 2a-c show illustrative wave springs in accordance with various embodiments. In particular, FIG. 2a shows an illustrative wave spring 200 that comprises a single, round piece of metal (e.g., steel) that is stamped to create a wave-like formation in the metal, as shown. The sizes of these waves and the material grade of the metal determine the spring force that the wave spring 200 will exert. FIG. 2b shows an illustrative wave spring 202. The wave spring 202 is similar to the wave spring 200, except that the metal in the wave spring 202 is flat. Similarly, FIG. 2c shows a wave spring 204. The wave spring 204 is similar to the wave spring 202 but comprises individual wave springs coupled to each other as shown. As explained above, other types of springs (e.g., coil springs) also may be used. The sizes and spring constants of the springs 200, 202 and 204 are application-specific and may be varied as desired.

FIG. 3 shows a top-down view of system 100 in accordance with embodiments of the invention. As shown and as described above, the system 100 comprises the assembly 102 that couples to the heat dissipator 106. In at least some embodiments, the assembly 102 comprises a flip-chip package. Other types of packages also may be used. The heat dissipator 106 may couple to a silicon surface 120 of the top plate 108. The screws 116 couple a silicon surface 120 of the top plate 108 (i.e., the surface to which the heat dissipator 106 couples) to the RSP 114. In accordance with embodiments, the screws 116 are not spring-mounted (i.e., the screws 116 couple the silicon surface to the RSP 114 without using springs). The spring 118 is disposed between the RSP 114 and the back plate 113 (as shown in FIG. 1).

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. An assembly, comprising:
a sub-assembly including a semiconductor package coupled to a printed circuit board (PCB);
multiple rigid connectors that couple the sub-assembly to a support structure; and
a spring, coupled to the support structure and positioned between the multiple rigid connectors, that supports at least some of the sub-assembly.

2. The assembly of claim 1, wherein the spring comprises a wave spring.

3. The assembly of claim 1, wherein at least one of the multiple rigid connectors is not spring-mounted.

4. The assembly of claim 1, wherein the spring is equidistant from at least two of the multiple rigid connectors.

5. The assembly of claim 1, wherein the support structure comprises a rigid support plate.

6. The assembly of claim 1, wherein said spring is the only spring in said assembly.

7. An apparatus, comprising:
a heat dissipator;
a top plate coupled to the heat dissipator and to a die, said die coupled to a printed circuit board (PCB);
a back plate coupled to the PCB;
connectors that couple the top plate to a rigid support plate; and
a spring that couples the back plate to the rigid support plate, the spring positioned between the connectors.

8. The apparatus of claim 7, wherein the spring comprises one or more stamped pieces of metal that are at least partially round and that have multiple waves.

9. The apparatus of claim 7, wherein the connectors include a screw that is not spring-mounted.

10. The apparatus of claim 7, wherein the spring is positioned approximately equidistant from each of said connectors.

11. An apparatus, comprising:
a chip assembly that includes a die and a printed circuit board (PCB) coupled to the die;
a rigid support plate;
rigid means for coupling the chip assembly to the rigid support plate; and
spring means for supporting the chip assembly, said spring means disposed between the chip assembly and the rigid support plate.

12. The apparatus of claim 11, wherein the spring means comprises a wave spring.

13. The apparatus of claim 11, wherein the rigid means comprises a screw that does not have any spring directly coupled to it.

14. The apparatus of claim 11, wherein the spring means is positioned approximately equidistant from a plurality of said rigid means.

15. The apparatus of claim 11, wherein the spring means is positioned between said rigid means and another rigid means for coupling the chip assembly to the rigid support plate.
